(19) United States
(12) Patent Application Publication
(10) Pub. No.: US 2024/0312129 A1
(43) Pub. Date: Sep. 19, 2024

(54) A DATA DRIVEN SURROGATE MODEL FOR PREDICTING FLOW FIELD PROPERTIES AROUND 3D OBJECTS

(71) Applicant: SRI International, Menlo Park, CA (US)

(72) Inventors: Anirban Roy, San Francisco, CA (US); Adam Derek Cobb, Washington, DC (US); Daniel Elenius, Redwood City, CA (US); Patrick Denis Lincoln, Woodside, CA (US); Susmit Jha, Redwood City, CA (US)

(21) Appl. No.: 18/509,024

(22) Filed: Nov. 14, 2023

Related U.S. Application Data
(60) Provisional application No. 63/385,325, filed on Nov. 29, 2022.

(51) Int. Cl. G06T 17/00; G06V 10/426

(52) U.S. Cl. CPC G06T 17/00; G06V 10/426

(57) ABSTRACT

In an example, a method for adapting a machine learning model includes receiving a digital representation of a three-dimensional (3D) object; learning, using a surrogate model, relationships between a plurality of points on a surface of the 3D object; and generating, using the surrogate model, one or more predictions about fluid properties along the surface of the 3D object.

This application claims the benefit of U.S. Patent Application No. 63/385,325, filed Nov. 29, 2022, which is incorporated by reference herein in its entirety.

### GOVERNMENT RIGHTS

This invention was made with Government support under contract number. FA8750-20-C-0002 awarded by the United States Air Force and the Defense Advanced Research Projects Agency, and under grant number CNS-1740079 awarded by the National Science Foundation. The Government has certain rights in this invention.

### TECHNICAL FIELD

This disclosure is related to machine learning systems, and more specifically to structure-aware flow-field predictions.

### BACKGROUND

Conventional computational fluid dynamics (CFD) surrogate models aim to predict high-level outputs such as overall drag and lift numbers. These models are typically trained on a dataset of CFD simulations, and they can be used to predict the performance of a design without having to run a full CFD simulation. However, these models do not consider the complete flow field. The flow field is a complex three-dimensional structure that contains a wealth of information about the physical behavior of the fluid. By predicting the complete flow field, it is possible to gain a deeper understanding of the design and to identify areas where it can be improved.

Existing approaches of predicting the flow field do not consider the structural dependencies in the output space. In other words, existing approaches may not be able to accurately predict the flow field in all regions of the design. Furthermore, CFD simulators take a considerable amount of time (from hours to days) to produce outputs because CFD simulators need to solve a set of complex differential equations that describe the flow of fluids. These equations are often nonlinear and coupled, which means that they are difficult to solve accurately and efficiently. To solve the aforementioned equations, CFD simulators use a variety of numerical analysis. These numerical analysis typically involve discretizing the flow domain into a mesh of small cells and then solving the equations for each cell. Accordingly, predicting the flow field may be very computationally expensive, especially for complex geometries and flow conditions.

### SUMMARY

A fluid is a state of matter that may flow and deform under the application of a shear stress. Fluids are made up of tiny particles that are constantly moving and interacting with each other. The particles in a fluid are not held together by any strong forces, so they may easily flow and deform. Fluids may be liquids or gases. Liquids are fluids that have a definite volume and take the shape of the container they are in. Gases are fluids that do not have a definite volume and expand to fill the container they are in.

The disclosure describes techniques for a data-driven surrogate model for computational fluid dynamics (CFD). A data-driven surrogate model for CFD is a model that may be used to predict fluid properties, such as, but not limited to, pressure and velocity, without having to perform a full CFD simulation. A data-driven surrogate model may be useful for a number of reasons, such as, but not limited to: speed, flexibility and interpretability. For example, surrogate models may be much faster to evaluate than CFD simulations, which may be computationally expensive, especially for complex geometries or flow conditions.

Furthermore, surrogate models may be used to predict fluid properties at new locations or under new conditions that were not included in the training data. In addition, surrogate models may sometimes provide insights into the physical mechanisms governing fluid flow that are not easily obtained from CFD simulations. Graph Transformer Networks (GTNs) are a type of neural network that may be used to learn relationships between nodes in a graph. In the context of CFD, a GTN may be used to learn relationships between different points on or near the surface of a 3D object. Information about relationships between different points may then be used to make predictions about the fluid properties at those points. To implement a data-driven surrogate model for CFD using a GTN, the following steps may be taken. A training dataset may be generated. This dataset may comprise pairs of input data and output data. The input data may describe the geometry of the 3D object and the flow conditions, and the output data may be the fluid properties at different points on the surface of the 3D object. The GTN may be trained using the training dataset.

The techniques may provide one or more technical advantages that realize at least one practical application. For example, the disclosed techniques may enable training the GTN to predict the output data from the input data. Once the GTN is trained, the trained GTN may be used to predict the fluid properties at new locations or under new conditions. The use of a GTN to implement a data-driven surrogate model for CFD has a number of advantages. First, GTNs are able to learn complex relationships between different points on the surface of a 3D object. In other words, GTNs may make more accurate predictions than simpler surrogate models. Second, GTNs are able to handle complex geometries and flow conditions. This flexibility makes the GTNs suitable for a wide range of CFD applications.

The techniques described in the disclosure may be applied to a variety of problems, such as structure-aware predictions that take into account the underlying structure of the 3D object. For example, a structure-aware prediction of the pressure field would account for the presence of cavities, protrusions, and other features on the surface of the object. GTNs are well-suited for making structure-aware predictions because they are able to learn relationships between different points on or near the surface of a 3D object. Information about relationships between different points may allow GTNs to predict how the fluid flow will be affected by the underlying structure of the object. A computing system could implement a simulation system to model fluid flow around a 3D object and to predict fluid properties along the surface of the object.

The speed and performance gain that GTNs may provide can improve the operation of the simulation system itself in terms of resource consumption in the following ways. GTNs may reduce the amount of computation that is required to solve the Navier-Stokes equations because GTNs may learn to predict the fluid flow at different points on the surface of the object based on the relationships between those points. In other words, the simulation system does not need to solve the Navier-Stokes equations at every point on the surface of the object. GTNs may allow the simulation system to run on less powerful hardware because the surrogate models that are constructed by GTNs are typically much smaller and faster than the Navier-Stokes equations themselves. GTNs may make it possible to simulate more complex 3D objects because GTNs may learn to predict the fluid flow around complex 3D objects without having to resort to expensive numerical methods.

In an aspect, a surrogate model may also be implemented as a Graph Convolutional Network (GCN). GCNs are typically implemented using a layered architecture, where each layer learns to aggregate the representations of the previous layer's neighbors. The output of the final layer may be the representation of the graph.

In an example, a method includes, receiving a digital representation of a three-dimensional (3D) object; learning, using a surrogate model, relationships between a plurality of points on a surface of the 3D object; and generating, using the surrogate model, one or more predictions about fluid properties along the surface of the 3D object.

In an example, a computing system comprises: an input device configured to receive a digital representation of a three-dimensional (3D) object; processing circuitry and memory for executing a machine learning system, wherein the machine learning system is configured to: learn, using a surrogate model, relationships between a plurality of points on a surface of the 3D object; and generate, using the surrogate model, one or more predictions about fluid properties along the surface of the 3D object.

In an example, non-transitory computer-readable media comprises machine readable instructions for configuring processing circuitry to: receive a digital representation of a three-dimensional (3D) object; learn, using a surrogate model, relationships between a plurality of points on a surface of the 3D object; and generate, using the surrogate model, one or more predictions about fluid properties along the surface of the 3D object.

The details of one or more examples of the techniques of this disclosure are set forth in the accompanying drawings and the description below. Other features, objects, and advantages of the techniques will be apparent from the description and drawings, and from the claims.

### BRIEF DESCRIPTION OF DRAWINGS

FIG. 1 is a block diagram of an example system and network for predicting fluid properties from a point cloud data in accordance with the techniques of the disclosure.

FIG. 2 is a block diagram illustrating an example system in accordance with the techniques of the disclosure.

FIG. 3 is a conceptual diagram illustrating an example of a GTN according to techniques of this disclosure.

FIG. 4 is a conceptual diagrams illustrating example GTN processing point cloud data according to techniques of this disclosure.

FIG. 5 is a flowchart illustrating an example mode of operation for a simulation system, according to techniques described in this disclosure.

Like reference characters refer to like elements throughout the figures and description.

### DETAILED DESCRIPTION

The disclosure describes techniques for techniques for a data-driven surrogate model for computational fluid dynamics (CFD). A simulation system may use a GTN to implement a surrogate model for making structure-aware predictions of the fluid properties. The goal of the disclosed techniques is to develop data-driven surrogate models that may be used to predict detailed simulation results from CFD simulators. Specifically, the disclosed techniques focus on predicting the flow characteristics, such as, but not limited to, the pressure field and the velocity field along the surface of a given 3D object.

CFD simulators are computationally expensive, especially for complex geometries or flow conditions. Accordingly, it may be difficult to use CFD simulations to explore a wide range of design options or to analyze the performance of existing products and systems. Data-driven surrogate models may be much faster than CFD simulators, while still providing accurate predictions.

Surrogate models may be trained on a dataset of CFD simulation results. Once the surrogate model is trained, the trained surrogate model may be used to predict the flow characteristics at new locations or under new conditions without having to perform a full CFD simulation. As noted above, the disclosed techniques employ a GTN to implement a data-driven surrogate model for predicting flow characteristics. GTNs are a type of neural network that may be used to learn relationships between nodes in a graph.

In the context of CFD, a GTN may be used to learn relationships between different points on the surface of a 3D object. Information about relationship between different points may then be used to make predictions about the flow properties at those points. GTNs may also be used to predict the fluid properties of points that are not on the surface of the object because the GTN may learn the relationships between different points in the 3D space, not just the points on the surface of the object. Accordingly, a GTN described herein may be well-suited for predicting the fluid properties of shock waves, which are often located away from the surface of the object, and/or the surface of the water around a watercraft. The present disclosure demonstrates that the disclosed surrogate model may provide accurate predictions of the pressure field and velocity field along the surface of a 3D object. The present disclosure also shows that the disclosed surrogate model is much faster than a CFD simulator.

Simpler surrogate models, such as convolutional neural networks (CNNs), are not able to learn complex relationships between different points as easily because CNNs are typically designed to learn relationships between pixels in an image, which are not the same as the relationships between points on the surface of a 3D object. As a result, GTNs are often able to make more accurate predictions than simpler surrogate models. For example, GTNs have been shown to be more accurate than CNNs at predicting the shape of a 3D object from a single image. GTNs may learn the relationship between the shape of an object and its function. For example, a GTN could be trained to predict the aerodynamic properties of an airplane wing based on its shape.

A surrogate model may be used to speed up the process of predicting fluid flow around a 3D object. The surrogate model could also be used to predict fluid flow at new locations or under new conditions that were not included in the training data. Additionally, the surrogate model may provide insights into the physical mechanisms governing fluid flow that are not easily obtained from CFD simulations. The techniques described in the present disclosure may provide a number of technical advantages, including, but not limited to: efficiency, detail and structure-awareness. The simulation system may be much more efficient than existing CFD simulators, while still accurately predicting the simulation outputs.

For example, the relative error of the disclosed simulation system may be less than approximately 5%, and the simulation speed may be approximately 500 times (500×) faster. The simulation outputs may be more detailed than those provided by existing CFD simulators.

For example, the simulation outputs may include a substantial portion of the flow field and, in some instances, a complete flow field. The simulation system may consider the structural dependencies in the output space while predicting the flow-fields. In other words, the simulation system may predict how the fluid flow will be affected by the underlying structure of the 3D object.

One or more technical advantages may be realized in a number of practical applications, such as, but not limited to: design exploration and analysis. The simulation system may be used to quickly explore a wide range of design options. Such exploration may help engineers to identify the best design for a particular application. The simulation system may be used to analyze the performance of existing products and systems. The analyzed information may be used to improve the design and performance of the analyzed products and systems.

Overall, the techniques described in the present disclosure may improve the way that fluid flow problems are solved. By providing more efficient, detailed, and structure-aware simulations, the disclosed techniques may enable engineers and scientists to design and optimize products and systems with greater confidence. In addition to the above, the improved running time of the simulation system may also speed up downstream tasks such as design exploration and analysis because engineers and scientists will be able to run more simulations in less time, which will give them more data to work with and make better decisions.

In summary, the present disclosure presents techniques for developing data-driven surrogate models for predicting detailed simulation results from CFD simulators. By replacing expensive CFD simulators with fast data-driven surrogate models, engineers and scientists may be able to explore a wider range of design options and analyze the performance of existing products and systems more efficiently. Following are some specific examples of how the proposed surrogate model could be used. An engineer could use the surrogate model to quickly explore a wide range of design options for a new aircraft wing. A scientist could use the surrogate model to analyze the performance of a new wind turbine under different wind conditions. A researcher could use the surrogate model to study the flow of blood around a diseased heart. Common CFD surrogate models aim to predict high-level outputs such as overall drag and lift numbers because these outputs are potentially the most important factors for engineers and scientists to consider when designing and optimizing products and systems. However, there are many cases where it is also important to be able to predict the complete flow field.

For example, engineers may need to know the flow field around a new aircraft wing in order to predict its performance. Scientists may need to know the flow field around a new wind turbine in order to predict its efficiency. Researchers may need to know the flow field around a diseased heart in order to develop new treatments.

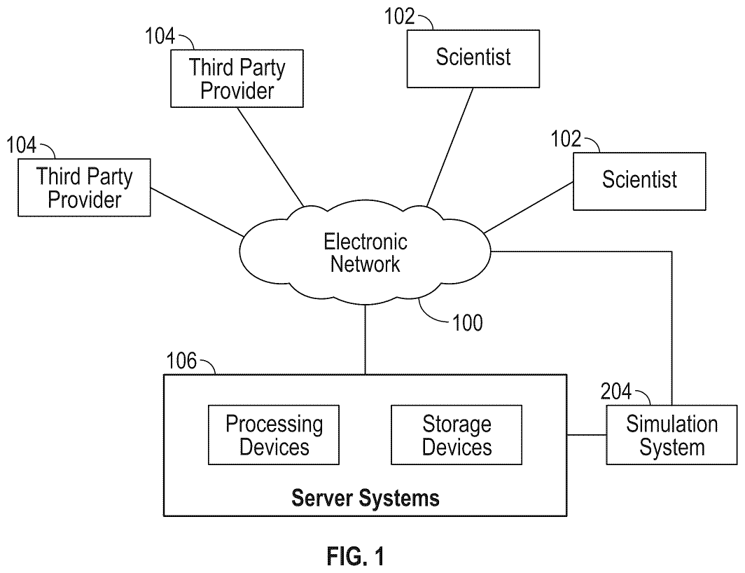

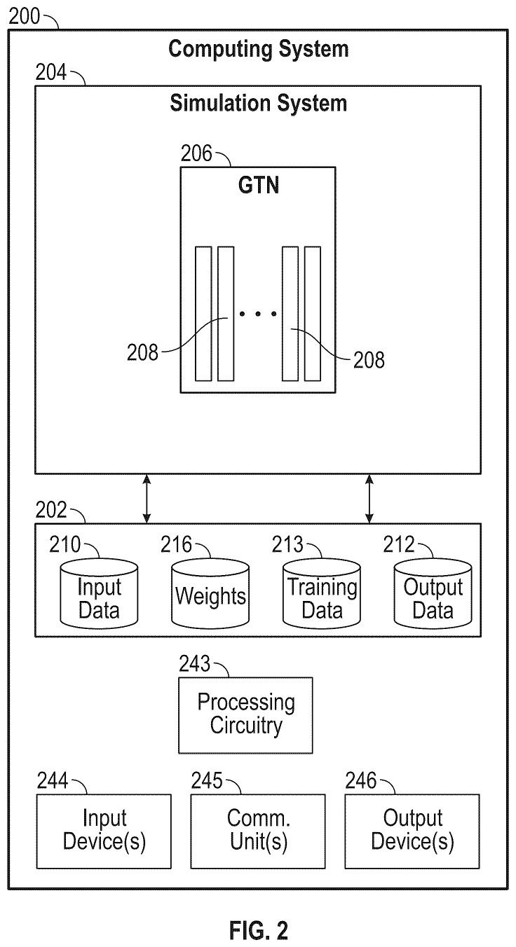

FIG. 1 is a block diagram of an example system and network for predicting fluid properties from a point cloud data in accordance with the techniques of the disclosure. Specifically, FIG. 1 depicts a plurality of scientists 102 and third party providers 104, any of whom may be connected to an electronic network 100, such as the Internet, through one or more computers, servers, and/or handheld mobile devices. Scientists 102 and/or third party providers 104 may create or otherwise obtain point cloud data of one or more 3D objects. The scientists 102 and/or third party providers 104 may also obtain any combination of object-specific information, such as type of the object, geometric shape of the object, geometric structure of the object, etc. Scientists 102 and/or third party providers 104 may transmit the images, point cloud data and/or object-specific information to server systems 106 over the electronic network 100. Server systems 106 may include storage devices for storing images and point cloud data received from scientists 102 and/or third party providers 104. Server systems 106 may also include processing devices for processing images and point cloud data stored in the storage devices. In an aspect, one or more processing devices may be connected a simulation system 204 having a surrogate model described below in conjunction with FIG. 2. The simulation system 204 may also include one or more processing devices (e.g., distributed over one or more networks or otherwise in communication with one another). In an aspect, the simulation system 204 may be configured to receive a digital representation of a 3D object; learn, using a surrogate model, relationships between a plurality of points on a surface of the 3D object; and generate, using the surrogate model, one or more predictions about fluid properties along the surface of the 3D object.

FIG. 2 is a block diagram illustrating an example computing system 200. In an aspect, computing system 200 may comprise an instance of the processing device in FIG. 1. As shown, computing system 200 comprises processing circuitry 243 and memory 202 for executing a simulation system 204 having a GTN model 206 comprising respective set of layers 208 that may form an overall framework for performing one or more techniques described herein.

Computing system 200 may be implemented as any suitable computing system, such as one or more server computers, workstations, laptops, mainframes, appliances, cloud computing systems, High-Performance Computing (HPC) systems (i.e., supercomputing) and/or other computing systems that may be capable of performing operations and/or functions described in accordance with one or more aspects of the present disclosure. In some examples, computing system 200 may represent a cloud computing system, server farm, and/or server cluster (or portion thereof) that provides services to client devices and other devices or systems. In other examples, computing system 200 may represent or be implemented through one or more virtualized compute instances (e.g., virtual machines, containers, etc.) of a data center, cloud computing system, server farm, and/or server cluster.

The techniques described in this disclosure may be implemented, at least in part, in hardware, software, firmware or any combination thereof. For example, various aspects of the described techniques may be implemented within processing circuitry 243 of computing system 200, which may include one or more of a microprocessor, a controller, a digital signal processor (DSP), an application specific integrated circuit (ASIC), a field-programmable gate array (FPGA), or equivalent discrete or integrated logic circuitry, or other types of processing circuitry. Processing circuitry 243 of computing system 200 may implement functionality and/or execute instructions associated with computing system 200. Computing system 200 may use processing circuitry 243 to perform operations in accordance with one or more aspects of the present disclosure using software, hardware, firmware, or a mixture of hardware, software, and firmware residing in and/or executing at computing system 200. The term “processor” or “processing circuitry” may generally refer to any of the foregoing logic circuitry, alone or in combination with other logic circuitry, or any other equivalent circuitry. A control unit comprising hardware may also perform one or more of the techniques of this disclosure.

In another example, computing system 200 comprises any suitable computing system having one or more computing devices, such as desktop computers, laptop computers, gaming consoles, smart televisions, handheld devices, tablets, mobile telephones, smartphones, etc. In some examples, at least a portion of system 200 is distributed across a cloud computing system, a data center, or across a network, such as the Internet, another public or private communications network, for instance, broadband, cellular, Wi-Fi, ZigBee, Bluetooth® (or other personal area network-PAN), Near-Field Communication (NFC), ultrawideband, satellite, enterprise, service provider and/or other types of communication networks, for transmitting data between computing systems, servers, and computing devices.

Memory 202 may comprise one or more storage devices. One or more components of computing system 200 (e.g., processing circuitry 243, memory 202) may be interconnected to enable inter-component communications (physically, communicatively, and/or operatively). In some examples, such connectivity may be provided by a system bus, a network connection, an inter-process communication data structure, local area network, wide area network, or any other method for communicating data. The one or more storage devices of memory 202 may be distributed among multiple devices.

Memory 202 may store information for processing during operation of computing system 200. In some examples, memory 202 comprises temporary memories, meaning that a primary purpose of the one or more storage devices of memory 202 is not long-term storage. Memory 202 may be configured for short-term storage of information as volatile memory and therefore not retain stored contents if deactivated. Examples of volatile memories include random access memories (RAM), dynamic random-access memories (DRAM), static random access memories (SRAM), and other forms of volatile memories known in the art. Memory 202, in some examples, may also include one or more computer-readable storage media. Memory 202 may be configured to store larger amounts of information than volatile memory. Memory 202 may further be configured for long-term storage of information as non-volatile memory space and retain information after activate/off cycles. Examples of non-volatile memories include magnetic hard disks, optical discs, Flash memories, or forms of electrically programmable memories (EPROM) or electrically erasable and programmable (EEPROM) memories. Memory 202 may store program instructions and/or data associated with one or more of the modules described in accordance with one or more aspects of this disclosure.

Processing circuitry 243 and memory 202 may provide an operating environment or platform for one or more modules or units (e.g., GTN model 206), which may be implemented as software, but may in some examples include any combination of hardware, firmware, and software. Processing circuitry 243 may execute instructions and the one or more storage devices, e.g., memory 202, may store instructions and/or data of one or more modules. The combination of processing circuitry 243 and memory 202 may retrieve, store, and/or execute the instructions and/or data of one or more applications, modules, or software. The processing circuitry 243 and/or memory 202 may also be operably coupled to one or more other software and/or hardware components, including, but not limited to, one or more of the components illustrated in FIG. 2.

Processing circuitry 243 may execute simulation system 204 using virtualization modules, such as a virtual machine or container executing on underlying hardware. One or more of such modules may execute as one or more services of an operating system or computing platform. Aspects of simulation system 204 may execute as one or more executable programs at an application layer of a computing platform.

One or more input devices 244 of computing system 200 may generate, receive, or process input. Such input may include input from a keyboard, pointing device, voice responsive system, video camera, biometric detection/response system, button, sensor, mobile device, control pad, microphone, presence-sensitive screen, network, or any other type of device for detecting input from a human or machine.

One or more output devices 246 may generate, transmit, or process output. Examples of output are tactile, audio, visual, and/or video output. Output devices 246 may include a display, sound card, video graphics adapter card, speaker, presence-sensitive screen, one or more USB interfaces, video and/or audio output interfaces, or any other type of device capable of generating tactile, audio, video, or other output. Output devices 246 may include a display device, which may function as an output device using technologies including liquid crystal displays (LCD), quantum dot display, dot matrix displays, light emitting diode (LED) displays, organic light-emitting diode (OLED) displays, cathode ray tube (CRT) displays, e-ink, or monochrome, color, or any other type of display capable of generating tactile, audio, and/or visual output. In some examples, computing system 200 may include a presence-sensitive display that may serve as a user interface device that operates both as one or more input devices 244 and one or more output devices 246.

One or more communication units 245 of computing system 200 may communicate with devices external to computing system 200 (or among separate computing devices of computing system 200) by transmitting and/or receiving data, and may operate, in some respects, as both an input device and an output device. In some examples, communication units 245 may communicate with other devices over a network. In other examples, communication units 245 may send and/or receive radio signals on a radio network such as a cellular radio network. Examples of communication units 245 may include a network interface card (e.g., such as an Ethernet card), an optical transceiver, a radio frequency transceiver, a GPS receiver, or any other type of device that can send and/or receive information. Other examples of communication units 245 may include Bluetooth®, GPS, 3G, 4G, and Wi-Fi® radios found in mobile devices as well as Universal Serial Bus (USB) controllers and the like.

In the example of FIG. 2, GTN model 206 may receive input data from an input data set 210 and may generate output data 212. Input data 210 and output data 212 may contain various types of information. For example, input data 210 may include point cloud data for a point cloud representation of a 3D object. Output data 212 may include a representation of flow field, a representation of pressure field, a representation of velocity field, and so on.

Each set of layers 208 may include a graph transformer layer. Each layer of the GTN model 206 may learn a new representation of the graph, which may then be used to make predictions about the fluid properties, a respective set of artificial neurons.

Simulation system 204 may process training data 213 to train the GTN model 206, in accordance with techniques described herein. For example, simulation system 204 may apply an end-to-end training method that includes processing training data 213. It should be noted that in various aspects another computing system may train the GTN model 206.

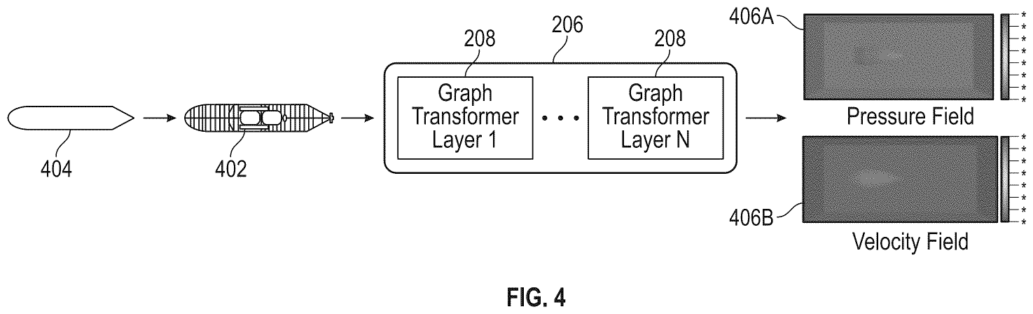

In an aspect, the input data 210 received by the simulation system 204 may include point cloud data for a point cloud representation of a 3D object. Point cloud data is a collection of 3D points, each of which is represented by a position vector in a coordinate system. An example point cloud representation of a 3D object (point cloud representation 404) is shown in FIG. 4. The point cloud data for the 3D object may be used to represent the surface of the object. In some cases, local dependencies for the point cloud may be captured via a self-attention mechanism, as described herein. In other words, the relationship between each point in the point cloud and its neighboring points may be taken into account when making predictions. Example 3D objects that may be represented by point cloud data may include, but are not limited to: aerial vehicles (i.e., aircraft and drones), ground vehicles (i.e., cars and trucks), subsurface vehicles (i.e., submarines and underwater vehicles), projectiles (i.e., rockets).

By using point cloud data to represent the surface of a 3D object, the simulation system 204 may make predictions about the flow field around the object at a very high resolution. Such predictions may be useful for a variety of applications, such as optimizing the design of vehicles and projectiles, and studying the flow of fluids around complex objects.

In an aspect, the simulation system 204 may implement the GTN model 206 to predict structured outputs for a point cloud representation of a 3D object. In effect, the GTN model 206 may function as a data-driven surrogate model that may be used for making structure-aware predictions of fluid properties, such as, but not limited to, pressure field and velocity field, for the 3D object.

GTNs are a type of neural network that overcomes certain limitations in graph neural networks (GNNs). More specifically, the GTN model 206 may learn new graph structures and node representations via convolution on learnt meta-path graphs. Such convolutions may allow the GTN model 206 to learn more complex relationships between nodes in a graph. In the context of CFD simulations, the GTN model 206 may be used to learn relationships between different points on the surface of a 3D object. Information about relationships between different points may then be used to make predictions about the fluid properties at those points.

As noted above, the GTN model implemented 206 in the simulation system 204 may include one or more layers (e.g., graph transformer layers 208). Each layer 208 of the GTN model 206 may learn a new representation of the graph, which may then be used to make predictions about the fluid properties.

The use of the GTN model 206 as a surrogate model in CFD simulations may have a number of advantages. The GTN model 206 may learn complex relationships between points on the surface of a 3D object, which may allow them to make more accurate predictions of the fluid properties. Additionally, the GTN model 206 is relatively fast to train and evaluate, which makes them suitable for use in real-time applications.

The following is a summary of the key advantages of using the GTN model 206 as a surrogate model in CFD simulations. Ability to learn complex relationships between points on the surface of a 3D object allows for more accurate predictions of the fluid properties. Relatively fast training and evaluation makes the GTN model 206 suitable for use in real-time applications. The ability to learn new graph structures and node representations allows the GTN model 206 to adapt to new types of 3D objects and flow conditions.

The simulation system 204 may process a point cloud representation of a 3D object and may build a graph over the points to capture the spatial structure. In other words, the simulation system 204 may create a network of nodes, where each node represents a point in the point cloud. The edges in the graph may represent the relationships between the points. It should be noted that to model the air-water surface in the design of watercraft, the simulation system 204 may use the GTN model 206 to construct a graph representation of the surface of the watercraft and the surrounding air/water. The nodes of the graph may be the points on the surface of the watercraft and in the surrounding air, and the edges of the graph may connect neighboring points. The GTN model 206 may then be trained to predict the relationship between each pair of nodes in the graph. Similarly, to model the air-road surface in the design of ground vehicles, the simulation system 204 may use the GTN model 206 to construct a graph representation of the surface of the vehicle and the surrounding air. The nodes of the graph may be the points on the surface of the vehicle and in the surrounding air, and the edges of the graph may connect neighboring points. The GTN model 206 may then be trained to predict the relationship between each pair of nodes in the graph. This information may then be used to generate predictions about the fluid properties near the surface of the 3D object. The predictions may be used to optimize the design of the 3D object or to control object's behavior in the environment.

The simulation system 204 may then use the GTN model 206 to make predictions of structured outputs, which may include fluid properties along the surface of or surrounding the 3D object. The GTN model 206 may explicitly consider the spatial structure in the output space when making predictions. In other words, the GTN model 206 may take into account the relationships between the points in the point cloud when making predictions about the fluid properties.

In an aspect, the predictions of the GTN model 206 may be point-wise. In other words, the GTN model 206 may predict the fluid properties at each point in the point cloud. Point-wise predictions may allow the simulation system 204 to output a substantial portion of the flow field, or even a complete flow field. Overall, the simulation system 204 may use the GTN model 206 to make structure-aware predictions of fluid properties along the surface of a 3D object.

The GTN model 206 may, in some instances, allow the simulation system 204 to output a detailed and accurate representation of the flow field. Following are some of the benefits of using the GTN model 206 to make structure-aware predictions of fluid properties. The GTN model 206 may learn complex relationships between points on the surface of a 3D object, which may allow the GTN model 206 to make more accurate predictions of the fluid properties. The GTN model 206 may output a substantial portion of the flow field, or even a complete flow field. The GTN model 206 may be relatively fast to train and evaluate, which may make it suitable for use in real-time applications. The GTN model 206 may be used to capture the spatial structure in both the input and output space. In other words, the GTN model 206 may learn relationships between points in the point cloud, both when encoding the input data 210 and when making predictions about the fluid properties.

The GTN model 206 may also, in some examples, handle an arbitrary number of points because the GTN model 206 may learn a graph representation of the point cloud, and the graph may be essentially any size. In some implementations, local dependencies for the point cloud may be exploited both for encoding the inputs and making predictions of fluid properties for the output points. In other words, the GTN model 206 may take into account the relationships between neighboring points in the point cloud, both when encoding the input data 210 and when making predictions about the fluid properties. This ability to capture spatial structure in both the input and output space, and to handle an arbitrary number of points, is a significant advantage of the GTN model 206 over existing GTNs that output a fixed-size vector or simply do not consider the structure in the output space. Following are some of the benefits of using a GTN to capture spatial structure in both the input and output space. The GTN model 206 may learn complex relationships between points on the surface of a 3D object, which may allow the GTN model 206 to make more accurate predictions of the fluid properties. The GTN model 206 may output a substantial portion of the flow field, or even a complete flow field. The GTN model 206 is relatively fast to train and evaluate, which may make it suitable for use in real-time applications.

A flow field depicts the movement of a fluid across a 3D object. The GTN model 206 may allow the simulation system 204 to compute a representation of the flow field. The representation of the flow field may include vectors for each of the points of the point cloud. In other words, the representation of the flow field may be used to describe the fluid properties at each point on the surface of the 3D object. The representation of the flow field may be output as the output data 212.

In an aspect, the simulation system 204 may provide users with a detailed and accurate understanding of the flow field around the 3D object. In some cases, the expected accuracy of the simulation system 204 may be below the usual expected range. This phenomenon could be due to a number of factors, such as the complexity of the 3D object or the flow condition. In an aspect, to distinguish these situations, the output data 212 may include data indicating confidence in the flow field representation.

Following are a few examples of how the flow field representation may be used. Aeronautical engineers may use flow field representations to design aircrafts that are more efficient and aerodynamic. For example, the aeronautical engineers may use the flow field representation to study the airflow over the aircraft's wings, and to predict the forces and torques acting on the aircraft. The predicted information may then be used to design wings that produce more lift and less drag. Another example of how the flow field representation may be used is in the design of wind turbines. Wind turbine engineers may use flow field representations to study the airflow around the turbine blades, and to predict the forces and torques acting on the blades. The predicted information may then be used to design blades that are more efficient and generate more power.

In summary, the GTN model 206 for predicting structured outputs may be used to ensure the following properties: consideration of a point cloud representation of the 3D object and building a graph over the points to capture the spatial structure and explicit consideration of the spatial structure in the output space while making the predictions in a graph transformer framework. A point cloud is a collection of points that represent the surface of a 3D object. A graph may be built over the points to capture the spatial relationships between them. The graph may be used to represent the geometric structure of the object, as well as the relationships between different parts of the object. A graph transformer network is a type of neural network that may be used to learn from graph-structured data.

The GTN model 206 may be used to make predictions on the graph, taking into account the spatial relationships between the nodes. Following is a simplified example of how the GTN model 206 for predicting structured outputs may be used. The input to the GTN model 206 may be a point cloud representation of a 3D object. The GTN model 206 may build a graph over the points in the point cloud. The GTN model 206 may use the graph to learn a representation of the object's geometric structure. The GTN model 206 may then use this representation to make predictions on the object's structured output.

For example, the GTN model 206 could be used to predict the object's surface normals, or its shape descriptors. The GTN model 206 may explicitly consider the spatial structure in the output space by using a graph transformer framework.

In an aspect, the simulation system 204 may either perform one or more actions to mitigate the negative effects of fluid properties and/or may communicate with an automated system, such as, but not limited to a design system configured to mitigate the negative effects of fluid properties along the surface of a 3D object. Some common methods include, but are not limited to, changing the shape of the object, adding surface features, using coating and using active control devices, among many others. The shape of the object may be changed to reduce drag, noise, and other negative effects. For example, a streamlined shape may be used to reduce drag on an aircraft wing. Surface features such as grooves and dimples may be added to the object to reduce drag and noise. For example, shark skin has a textured surface that helps to reduce drag. Coatings may be applied to the surface of the object to change its properties and reduce negative effects. For example, a coating may be used to reduce the friction between the object and the fluid. Active control devices such as suction panels and jet actuators may be used to modify the flow of fluid around the object in real time to reduce negative effects. For example, a suction panel may be used to reduce the drag on a ground vehicle body. The specific action that is taken to mitigate the negative effects of fluid properties will depend on the specific application and the nature of the problem.

In an aspect, the techniques described herein may also be applied to the flow of electricity and electromagnetic fields. More specifically, the disclosed techniques may be applied to design of antennas for radio-frequency transmission or reception. Antennas are arrays of electrical conductors of specified shapes, some connected to a receiver or transmitter. A simple single conducting wire standing perpendicular to the earth's surface may be an antenna, providing omnidirectional performance in all horizontal directions. A parabolic dish not connected to any transmitter or receiver, with a simple conductor wire connected to a transmitter or receiver placed at the focus of the parabola may provide a strong beam pattern of sensitivity in the direction of the axis of the parabola for certain wavelengths of radio-frequency energy. The design of shapes of conducting elements of an antenna, given a desired shape of pattern of sensitivity in certain wavelengths, is a complex problem that may be addressed with the techniques disclosed here. One simplification of the general antenna design problem is the design of two-dimensional structured grid with “pixelated” areas of conductive or nonconductive material. Even the design of such antennas is nontrivial, and the techniques described here may be gainfully applied. Topology optimization is a method of designing structures with the best possible performance for a given set of constraints. In the context of antenna design, topology optimization may be used to design antennas with the desired electrical performance, such as a low reflection coefficient across a given frequency band. To perform topology optimization on an antenna design, the antenna may be represented as a 2D structured grid for metal deposition. The grid may then be represented by a graph, with nodes as the grid elements and edges between nodes that are adjacent to each other. A graph surrogate model, such as the GTN model 206 or graph convolutional network (GCN), may then be used to predict the desired performance metrics of the antenna, such as the reflection coefficient corresponding to a frequency band. The flow of electromagnetic waves (synchronized oscillations of electric and magnetic fields) around the structure represented by the graph model may be predicted using well-known techniques based on Maxwell's equations. This technique may be generalized to three-dimensional structures using another graph surrogate model.

In an aspect, techniques described herein may be extended to complex combination surfaces, some moving in relations to each other, including, but not limited to, ducted fans, a combination of propellers and cylindrical ducts or shrouds, as appear in high-bypass turbofans used on many modern airliners. In these cases, the GTN model 206 may consider a graph representation of not only the solid surfaces, but also of some fluid regions to estimate the pressure and velocity over the surface and the fluid regions, enabling the estimation of performance and optimization of performance of such complex combinations of moving parts (propellers) with non-moving parts (ducts or shrouds), including complex fluid flows inside jet engines and turbofans. More specifically, the techniques described herein may be used to predict the fluid flow properties around a fixed shape, like a cylindrical duct, and may also be used to predict the fluid flow properties around a moving shape like a spinning propeller, and may also be used to predict the fluid flow properties around complex combinations of moving and non-moving parts like a spinning propeller inside a cylindrical duct. Such combinations may include, but are not limited to, the prediction of fluid flows around a ground vehicle, with a fixed surface (the roadway), a moving object (the body of the vehicle) and spinning objects (wheels), and heating, ventilation, and cooling systems (with fixed duct work and moving fans).

Furthermore, the disclosed techniques may be used to estimate additional properties such as thermodynamic properties beyond the pressure and velocity fields, consider the non-linear interactions between these properties, and predict multiple properties simultaneously. To estimate thermodynamic properties such as temperature, density, and enthalpy, the GTN model 206 may be trained on a dataset of thermodynamic measurements for a variety of solid surface and fluid region geometries. The GTN model 206 may then be used to predict the thermodynamic properties at any point in the solid surface and fluid regions. An example application is the design of catalytic converters, efficiently promoting certain chemical reactions as fluids such as exhaust gasses or reacting liquids flow over a catalytic surface. Automobile catalytic converters combine oxygen with carbon monoxide and other partially-burned hydrocarbons in internal-combustion-engine exhaust, producing carbon dioxide and water vapor. Improved design of catalytic converters could reduce the size and weight and material costs (precious metals such as platinum) of catalytic converters. For this application, the simulation system 204 may use a simple model of surface chemical catalysis together with the previously described fluid flow prediction, predicting the chemical properties (a “field” representing chemical concentrations) of the fluids flowing around the surfaces in addition to their pressure and velocity fields. Microfluidic systems and general handling of small-volumes of liquids for biological sample testing and experimentation is another example application where representations of fluid properties beyond pressure and velocity may be useful in optimizing fluid-system designs. Combustion chamber design (for rocket engines, internal combustion engines, coal-, oil-, or gas-fueled power plants, or other uses) is another application of this multi-physics approach, combining representation of fields of pressure and velocity, but also chemical concentrations, and temperature, predicting performance of the rocket engine or other device, for example.

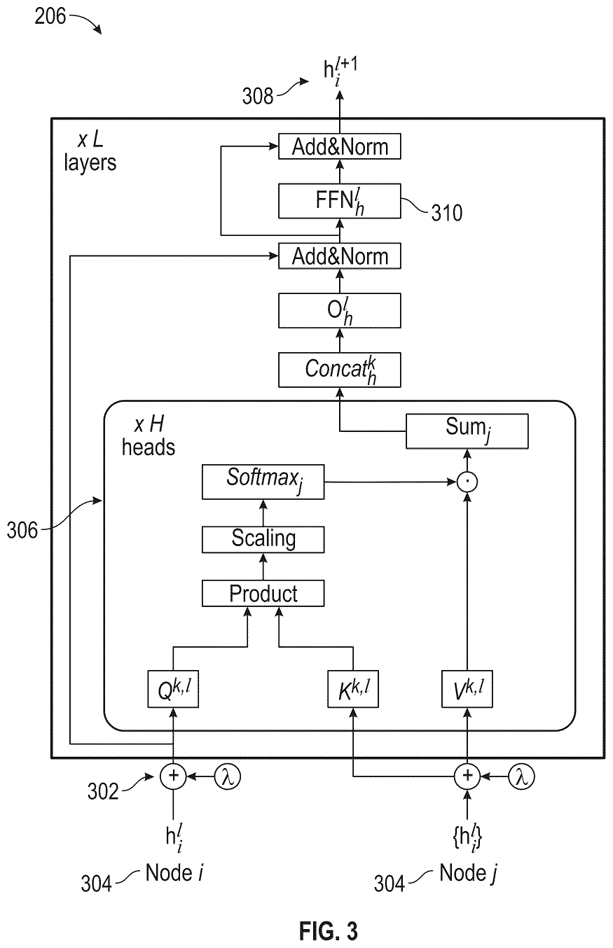

FIG. 3 is a conceptual diagram illustrating an example of a GTN according to techniques of this disclosure. In the example illustrated in FIG. 3 the goal of the GTN model 206 is to generate a fairing shape with suitable CFD characteristics and volume requirements. Following is a comparison of the GTN model 206 with alternative approaches/techniques. A first option to achieve the aforementioned goal it to use a surrogate model on parametric vector representations of fairing shapes. A parametric vector representation of a fairing shape is a compact way to represent the shape. The parametric vector representation may be useful for storing and manipulating the shape data.

A surrogate model is a model that may be used to approximate the behavior of a complex system. A simple surrogate model, such as a deep neural network, may be used to learn the relationship between the parametric vector representation of a fairing shape and its CFD characteristics and volume requirements. However, a parametric vector representation of a fairing shape may not be able to represent all possible fairing shapes. Accordingly, a parametric vector representation may limit the ability of the surrogate model to generate fairing shapes with the desired CFD characteristics and volume requirements. Overall, the aforementioned first option is a potential approach for generating fairing shapes with suitable CFD characteristics and volume requirements. However, it is important to be aware of the limitations of the parametric vector representation and the surrogate model. Following are some specific examples of how the limitations of the parametric vector representation and the surrogate model could manifest. The parametric vector representation may not be able to represent fairing shapes with complex features, such as, but not limited to, sharp edges or undercuts. The surrogate model may not be able to accurately predict the CFD characteristics and volume requirements of fairing shapes that are outside of the training data.

A second option to achieve the aforementioned goal it to use a surrogate model on 3D fairing shapes (tensor representation). A tensor representation of a fairing shape may be used to represent any possible fairing shape. The tensor representation may give the surrogate model the flexibility to generate fairing shapes with a wide range of features. The tensor representation of a fairing shape may capture more information about the shape than a parametric vector representation. Accordingly, the tensor representation may lead to more accurate predictions of the CFD characteristics and volume requirements of the fairing shape, as compared to the parametric vector representation.

However, the surrogate model should be able to handle arbitrary 3D shapes. Handling arbitrary 3D shapes may be challenging to achieve using tensor representation, especially for complex shapes.

The surrogate model should be able to learn the relationship between the structure of the fairing shape and its CFD characteristics and volume requirements. Learning such relationship may be challenging for large and complex fairing shapes. Overall, the aforementioned second option is a potential approach for generating fairing shapes with suitable CFD characteristics and volume requirements. However, it is important to be aware of the challenges involved in developing a surrogate model that can handle arbitrary 3D shapes and learn the relationship between the structure of the fairing shape and its CFD characteristics and volume requirements.

Following are some specific examples of how the challenges of developing a surrogate model for the aforementioned second option could manifest. First, it may be difficult to develop a surrogate model that may accurately predict the CFD characteristics and volume requirements of fairing shapes with complex features, such as, but not limited to, sharp edges or undercuts. Second, it may be difficult to develop a surrogate model that can scale to large and complex fairing shapes.

To address the aforementioned challenges, it may be necessary to use a new type of surrogate model, such as a GTN. GTNs are well-suited for learning from data that is represented as graphs, which may be used to represent the structure of fairing shapes. Additionally, it may be necessary to use a more efficient training algorithm and a more efficient surrogate model architecture.

Graphs may capture arbitrary shapes through the point clouds because the point cloud may be used to construct a graph, and the graph may be used to represent the structure of the fairing shape.

The surrogate model may first construct a graph over the input point cloud. The model may then use a graph transformer network to learn a representation of the fairing shape from the graph. The model may the uses this representation of the fairing shape to predict the CFD characteristics and volume requirements of the fairing shape. Graph transformers may learn to represent arbitrary shapes, which may give the surrogate model the flexibility to generate fairing shapes with a wide range of features.

In an aspect, graph transformers may learn to capture the complex relationships between the points in a point cloud, which may lead to more accurate predictions of the CFD characteristics and volume requirements of the fairing shape. In addition, graph transformers may scale to large and complex fairing shapes.

Following are some specific examples of how a surrogate model based on graph transformers on 3D point clouds could be used to generate fairing shapes with suitable CFD characteristics and volume requirements. The surrogate model could be used to generate fairing shapes that are optimized for specific CFD characteristics, such as, but not limited to, drag or lift. The surrogate model could be used to generate fairing shapes that meet specific volume requirements.

In an aspect, the GTN model 206 shown in FIG. 3 is permutation invariant because the GTN model 206 may use positional encoding 302 to learn the relative positions of the nodes 304 in the graph. In other words, the GTN model 206 does not care about the order of the nodes, as long as the relative positions are preserved. Permutation invariance property may be useful for tasks such as predicting the CFD characteristics of a fairing shape, as the fairing shape may be represented as a graph with the nodes 304 representing the points in the point cloud and the edges (not shown in FIG. 3) representing the spatial relationships between the points. In an aspect, the GTN model 206 is structure-aware because the GTN model 206 may use learned multi-head attention 306 to learn the relationships between the nodes 304 in the graph. In other words, the GTN model 206 may learn to capture the complex relationships between the points in a point cloud, which may lead to more accurate predictions of the CFD characteristics and volume requirements of the fairing shape. In an aspect, the GTN model 206 is scalable and efficient because the GTN model 206 may use shared convolutional operations. In other words, the GTN model 206 may learn to capture the complex relationships between the nodes 304 in the graph without having to learn a separate set of parameters for each node. Such ability to capture the complex relationships between the nodes 304 in the graph makes the GTN model 206 more efficient and easier to train. Overall, the GTN model 206 is a powerful tool for learning from graph-structured data. As discussed above, the GTN model 206 is permutation invariant, structure-aware, and scalable and efficient. The aforementioned properties make the GTN model 206 well-suited for tasks such as generating fairing shapes with suitable CFD characteristics and volume requirements. Following are some specific examples of how the permutation invariance, structure-awareness, and scalability and efficiency of graph transformers may be beneficial for generating fairing shapes with suitable CFD characteristics and volume requirements. The GTN model 206 may be used to generate fairing shapes with arbitrary features, such as sharp edges or undercuts, because the GTN model 206 does not care about the order of the nodes 304 in the graph, as long as the relative positions are preserved. The GTN model 206 may be used to generate fairing shapes that are optimized for specific CFD characteristics, such as drag or lift, because the GTN model 206 may learn to capture the complex relationships between the points in a point cloud, which may lead to more accurate predictions of the CFD characteristics of the fairing shape. The GTN model 206 may be used to generate fairing shapes for large and complex aircraft because the GTN model 206 is scalable and efficient, and the GTN model 206 may learn to capture the complex relationships between the points in a point cloud without having to learn a separate set of parameters for each node 304.

As shown in FIG. 3, at 308, the GTN model 206 may perform a node embedding. The node embedding 308 is a representation of the node 304 that captures its local features. At 306, the GTN model 206 may perform multi-head attention over neighbors. Multi-head attention over neighbors 306 allows the GTN model 206 to learn the relationships between the node 304 and its neighbors. Multi-head attention over neighbors 306 may be useful for tasks such as predicting the CFD characteristics of a fairing shape, as the fairing shape may be represented as a graph with the nodes 304 representing the points in the point cloud and the edges representing the spatial relationships between the points. In an aspect, the multi-head attention mechanism 306 may be implemented by first computing a similarity score between each node 304 and its neighbors. The similarity score may then be used to weight the contributions of the neighbors to the node's embedding 308. This process may be repeated multiple times, with each repetition using a different set of parameters. The output of the multi-head attention mechanism 306 may be a new embedding 308 for the node that captures the relationships between the node 304 and its neighbors. Input to the GTN model 206 may be a graph with nodes and edges. The GTN model 206 may learn a representation of each node that captures its local features by performing the node embedding 308. The GTN model 206 may learn the relationships between each node 304 and its neighbors by performing the multi-head attention over neighbors 306. The GTN model 206 may output the new embedding 308 for each node that captures the relationships between the node 304 and its neighbors. The new embedding 308 for each node 304 may then be used to make predictions about the CFD characteristics of the fairing shape.

A graph transformer layer 208 (shown in FIG. 2) is a building block of the GTN model 206. In an aspect, the node embedding 308, multi-head attention over neighbors 306 and feedforward network 310 may all be components of the graph transformer layer 208. Once again, the node-embedding component 308 may learn a representation of each node 304 in the graph that captures its local features. The multi-head attention over neighbors component 306 may learn the relationships between each node 304 and its neighbors. The feedforward network component 310 may learn a non-linear transformation of the node embeddings 308. The graph transformer layer may be implemented by first computing the node embeddings. The output of the feedforward network 310 may be a new set of node embeddings 308 that capture both the local features and the relationships between the nodes 304 in the graph. Positional encoding 302 is a technique that may be used to learn the relative positions of the nodes 304 in the graph. Positional encoding 302 may be important because the positional encoding 302 allows the GTN model 206 to learn the relationships between the nodes 304 in the graph even if the nodes 304 are not ordered. In an aspect, the positional encoding 302 may be implemented using a sinusoidal function. The sinusoidal function may be applied to each node 304 in the graph, with the frequency of the sinusoidal function depending on the node's 304 position in the graph. Positional encoding 302 may allow the GTN model 206 to learn the relative positions of the nodes 304 in the graph. Input to the GTN model 206 may be a graph with nodes and edges. Positional encoding 302 may be added to the node embeddings 308 before they are passed to the multi-head attention mechanism 306. The positional encoding 302 may allow the GTN model 206 to learn the relative positions of the nodes 304 in the graph even if the nodes 304 are not ordered.

FIG. 4 is a conceptual diagrams illustrating example GTN model on point cloud according to techniques of this disclosure. More specifically, FIG. 4 illustrates that a surrogate model based on graph transformers (GTN model 206) on 3D point clouds may be used to generate fairing shapes with suitable CFD characteristics and volume requirements. A uniformly sampled 3D point cloud 402 (2048 points) may be used to represent the input to the GTN model 206. The point cloud 402 may be used to construct a graph, where the nodes represent the points in the point cloud 402 and the edges represent the spatial relationships between the points.

In an aspect, the GTN model 206 may be trained on a dataset of 1000 fairing shapes. The GTN model 206 may then be tested on a separate dataset of 1000 fairing shapes. The GTN model 206 may be able to predict the flow field around the fairing shapes with high accuracy. The GTN model may also be able to achieve a speedup of 500× compared to traditional CFD simulations.

In an aspect, the speedup of 500× may be achieved because the GTN model 206 does not need to solve the Navier-Stokes equations directly. Instead, the GTN model 206 may learn a mapping from the fairing shape to the flow field. This mapping may be used to predict the flow field around new fairing shapes very quickly. Overall, the results show that the disclosed GTN model 206 is able to predict the flow field around fairing shapes with high accuracy and speed. The disclosed GTN model 206 could be a valuable tool for engineers and scientists (e.g., scientists 102 in FIG. 1) who need to design fairing shapes that are both aerodynamically efficient and lightweight. Following is a specific example of how the speedup could be beneficial. An engineer could use the GTN model 206 to predict the flow field around a new fairing shape. These predictions may allow the engineer to identify any areas where the fairing shape is not aerodynamically efficient. The engineer could then make changes to the fairing shape to improve its aerodynamic performance. The disclosed model could also be used to design fairing shapes for complex shapes, such as aircraft and spacecraft. Such design would be difficult and time-consuming to complete using traditional CFD simulations.

A 3D model 404 is a digital representation of a three-dimensional object. The 3D models 404 may be created using a variety of methods, such as, but not limited to, CAD software or 3D scanning. 3D models 404 may be used for a variety of purposes, such as design, manufacturing, and visualization. A stereolithography (STL) file is a standard file format for storing 3D models 404. STL files are typically used to share 3D models 404 between different software applications. OBJ is another popular 3D model format. OBJ is a text-based format that may store the geometry of a 3D model as a series of vertices, faces, and textures. OBJ files are also relatively small and easy to use, but they may be more complex to create and edit than STL files. A sampled 3D point cloud 402 is a collection of points that represent the surface of a three-dimensional object. Point clouds 402 may be created using a variety of methods, such as 3D scanning or lidar.

As shown in FIG. 4, the GTN model 206 may generate flow field representation 406a-b. The flow field depicts the movement of a fluid across a 3D object. The representation of the flow field 406A-B may include vectors for each of the points of the point cloud 402. In other words, the representation of the flow field 406A may be used to describe the fluid properties at each point on the surface of the 3D object. In a non-limiting example, the GTN model 206 may generate the representation of the pressure field 406A and the representation of the velocity field 406B.

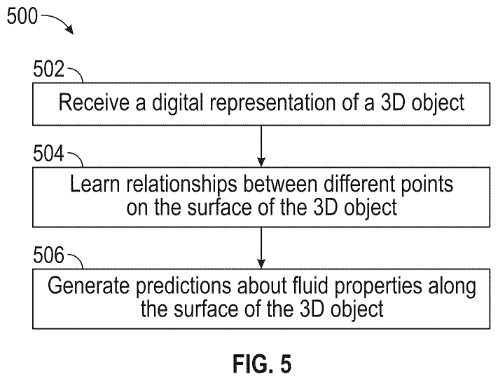

FIG. 5 is a flowchart illustrating an example mode of operation for a simulation system, according to techniques described in this disclosure. Although described with respect to computing system 200 of FIG. 2 having processing circuitry 243 that executes simulation system 204, mode of operation 500 may be performed by a computation system with respect to other examples of machine learning systems described herein.

In mode operation 500, processing circuitry 243 executes simulation system 204. Simulation system 204 may receive a digital representation of a 3D object (502). Simulation system 204 may learn relationships between a plurality of different points on the surface of the 3D object (504) using a graph neural network (e.g., GTN model 204). Simulation system 204 may next generate one or more predictions about fluid properties along the surface of the 3D object based on the learned relationships between the plurality of points on the surface of the 3D object (506). In an aspect, the simulation system 204 may provide accurate predictions of the pressure field 406A and the velocity field 406B along the surface of the 3D object.

The techniques described in this disclosure may be implemented, at least in part, in hardware, software, firmware or any combination thereof. For example, various aspects of the described techniques may be implemented within one or more processors, including one or more microprocessors, digital signal processors (DSPs), application specific integrated circuits (ASICs), field programmable gate arrays (FPGAs), or any other equivalent integrated or discrete logic circuitry, as well as any combinations of such components. The term “processor” or “processing circuitry” may generally refer to any of the foregoing logic circuitry, alone or in combination with other logic circuitry, or any other equivalent circuitry. A control unit comprising hardware may also perform one or more of the techniques of this disclosure.

Such hardware, software, and firmware may be implemented within the same device or within separate devices to support the various operations and functions described in this disclosure. In addition, any of the described units, modules or components may be implemented together or separately as discrete but interoperable logic devices. Depiction of different features as modules or units is intended to highlight different functional aspects and does not necessarily imply that such modules or units must be realized by separate hardware or software components. Rather, functionality associated with one or more modules or units may be performed by separate hardware or software components or integrated within common or separate hardware or software components.

The techniques described in this disclosure may also be embodied or encoded in computer-readable media, such as a computer-readable storage medium, containing instructions. Instructions embedded or encoded in one or more computer-readable storage mediums may cause a programmable processor, or other processor, to perform the method, e.g., when the instructions are executed. Computer readable storage media may include random access memory (RAM), read only memory (ROM), programmable read only memory (PROM), erasable programmable read only memory (EPROM), electronically erasable programmable read only memory (EEPROM), flash memory, a hard disk, a CD-ROM, a floppy disk, a cassette, magnetic media, optical media, or other computer readable media.

What is claimed is:

1. A method comprising:
receiving a digital representation of a three-dimensional (3D) object;
learning, using a surrogate model, relationships between a plurality of points on a surface of the 3D object; and
generating, using the surrogate model, one or more predictions about fluid properties along the surface of the 3D object.

2. The method of claim 1, wherein the surrogate model comprises a Graph Transformer Network (GTN) model.

3. The method of claim 2, wherein the digital representation comprises point cloud data.

4. The method of claim 3, further comprising:
converting the digital representation of the 3D object into graph-structured data prior to learning the relationships between the plurality of points on the surface of the 3D object.

5. The method of claim 4,
wherein converting the digital representation of the 3D object into the graph-structured data comprises generating a graph representing a shape of the 3D object using the point cloud data, and
wherein the generated graph comprises a plurality of nodes representing the plurality of points on the surface of the 3D object in the point cloud and a plurality of edges representing spatial relationships between the plurality of points on the surface of the 3D object.

6. The method of claim 5, wherein learning the relationships between the plurality of points comprises learning, by the GTN model, the relationships between the plurality of nodes in the generated graph using one or more shared convolutional operations.

7. The method of claim 6, wherein learning the relationships between the plurality of nodes comprises performing, by the GTN model, multi-head attention over neighbors.

8. The method of claim 1, wherein the 3D object comprises one of: an aerial vehicle, a ground vehicle, a watercraft, a subsurface vehicle, a projectile.

9. The method of claim 1, wherein the one or more predictions comprise one of: heat, pressure, velocity, radio frequency and types thereof.

10. The method of claim 1, further comprising:
receiving a digital representation of an environment near the 3D object;
learning, using the surrogate model, relationships between the plurality of points on the surface of the 3D object and/or a plurality of points near the surface of the 3D object; and
generating, using the surrogate model, one or more predictions about fluid properties of the environment near the surface of the 3D object.

11. The method of claim 10, wherein the digital representation of the 3D object is different from the digital representation of the environment near the 3D object.

12. The method of claim 1, further comprising:
performing an action to mitigate one or more negative effects of the fluid properties along the surface of the 3D object based on the one or more predictions about the fluid properties along the surface of the 3D object.

13. A computing system comprising:
an input device configured to receive a digital representation of a three-dimensional (3D) object;
processing circuitry and memory for executing a machine learning system, wherein the machine learning system is configured to:
learn, using a surrogate model, relationships between a plurality of points on a surface of the 3D object; and
generate, using the surrogate model, one or more predictions about fluid properties along the surface of the 3D object.

14. The computing system of claim 13, wherein the surrogate model comprises a Graph Transformer Network (GTN) model.

15. The computing system of claim 14, wherein the digital representation comprises point cloud data.

16. The computing system of claim 15, wherein the machine learning system is further configured to:
convert the digital representation of the 3D object into graph-structured data prior to learning the relationships between the plurality of points on the surface of the 3D object.

17. The computing system of claim 16, wherein the machine learning system is further configured to:
wherein the machine learning system configured to convert the digital representation of the 3D object into the graph-structured data is further configured to generate a graph representing a shape of the 3D object using the point cloud data, and
wherein the generated graph comprises a plurality of nodes representing the plurality of points on the surface of the 3D object in the point cloud and a plurality of edges representing spatial relationships between the plurality of points on the surface of the 3D object.

18. The computing system of claim 17, wherein the machine learning system configured to learn the relationships between the plurality of points is further configured to learn, by the GTN model, the relationships between the plurality of nodes in the generated graph using one or more shared convolutional operations.

19. The computing system of claim 18, wherein the machine learning system configured to learn the relationships between the plurality of nodes is further configured to perform, by the GTN model, multi-head attention over neighbors.

20. Non-transitory computer-readable media comprising machine readable instructions for configuring processing circuitry to:
receive a digital representation of a three-dimensional (3D) object;
learn, using a surrogate model, relationships between a plurality of points on a surface of the 3D object; and
generate, using the surrogate model, one or more predictions about fluid properties along the surface of the 3D object.
